(19) United States
(12) Patent Application Publication
(10) Pub. No.: US 2025/0364743 A1
(43) Pub. Date: Nov. 27, 2025

(54) FLOATING Z-STACKED COMPRESSION CONNECTOR

(71) Applicant: DELL PRODUCTS L.P., Round Rock, TX (US)

(72) Inventors: Arnold Thomas Schnell, Hutto, TX (US); Qinghong He, Austin, TX (US)

(21) Appl. No.: 18/673,608

(22) Filed: May 24, 2024

(51) Int. Cl. H01R 12/91; H01R 12/70; H01R 12/71; H01R 43/26

(52) U.S. Cl. CPC H01R 12/91; H01R 12/7047; H01R 12/716; H01R 43/26

(57) ABSTRACT

A connector apparatus is provided for electrically connecting and mechanically affixing a first PCB to a second PCB. The connector apparatus includes a flex connector and a connector mount. The flex connector has a first compression connector to provide electrical connections to the first PCB, a second compression connector to provide electrical connections to the second PCB, and a flex cable coupled to the first and second compression connectors. The connector mount is coupled between the first and second compression connectors.

### FIELD OF THE DISCLOSURE

This disclosure generally relates to information handling systems, and more particularly relates to a floating z-stacked compression connector in an information handling system.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

A connector apparatus may be provided for electrically connecting and mechanically affixing a first PCB to a second PCB. The connector apparatus may include a flex connector and a connector mount. The flex connector may have a first compression connector to provide electrical connections to the first PCB, a second compression connector to provide electrical connections to the second PCB, and a flex cable coupled to the first and second compression connectors. The connector mount may be coupled between the first and second compression connectors.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram illustrating an information handling system as may be known in the art;

FIGS. 2A is a block diagram illustrating an information handling system according to an embodiment of the present disclosure;

FIG. 2B is a block diagram of a connector arrangement as found on the information handling system of FIG. 2A;

FIGS. 3A-3C illustrate various configurations of the connector arrangement of FIG. 2B;

FIG. 4A illustrates a use case of the configuration of the connector arrangement shown in FIG. 3B;

FIG. 4B illustrates another use case of the configuration of the connector arrangement shown in FIG. 3C;

FIGS. 5A and 5B illustrate a connector arrangement according to another embodiment of the present disclosure; and

FIG. 6 is a block diagram illustrating a generalized information handling system according to another embodiment of the present disclosure;

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

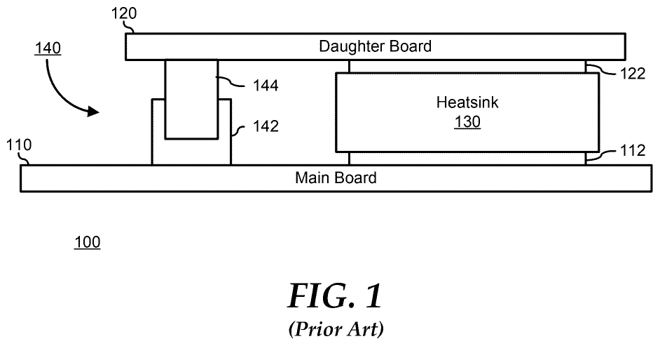

FIG. 1 illustrates an information handling system 100 as may be known in the art, including a main board 110, a daughter board 120, a heatsink 130, and a connector 140. Main board 110 includes a component 112 and daughter board 120 includes a component 222. Components 112 and 122 may be understood to represent integrated circuit devices that generate large amounts of heat when in operation. For example, component 112 may represent a processor, a system-on-a-chip (SoC), another heat-generating device, or the like, and component 122 may represent a graphics processor, a chipset component, another heat-generating device, or the like. As such, information handling system 100 is arranged in a compact arrangement where main board 110 is on the bottom of the information handling system with component 112 on the top of the main board. Heatsink 130 is firmly thermally and mechanically affixed to the top of component 112 to remove heat from the component. Information handing system 100 is further arranged with daughter board 120 located above main board 110 with component 122 on the bottom of the daughter board. Heatsink 130 is further firmly thermally and mechanically affixed to the bottom of component 122 to remove heat from the component. Thus, the compactness of information handling system 100 is enhanced by combining the thermal solutions for components 112 and 122 into a single element, viz., heatsink 130.

Daughter board 120 is mechanically affixed and electrically connected to main board 110 by connector 140. As such, connector 140 includes a main board connector element 142 and a daughter board connector element 144. As illustrated, main board connector element 142 represents a socket-type connector element and daughter board connector element 144 represents a plug-type connector element, but this is not a necessary arrangement, and main board connector element 142 my represent a plug-type connector element and daughter board connector element 144 may represent a socket-type connector element. Further, connector 140 may represent a pin-and-socket type of connector where either main board connector element 142 or daughter board connector element 144 represents the pin-type connector element and the complimentary connector element represents the socket-type connector element. In general, connector 140 may represent any suitable connector arrangement as needed or desired. Information handling system 100 may further include an additional stabilizing element between main board 110 and daughter board 120 to support any cantilevered portion of the daughter board, as needed or desired.

It has been understood by the inventors of the current disclosure that arrangements similar to information handling system 100 are subject, based upon various component stack-up tolerances, to unacceptable variances in the distance between the main board and the daughter board. For example, in a typical manufacturing environment, a heatsink may be fabricated with a height tolerance of up to one (1) millimeter (mm). In consequence of the varying distances, a skew-angle may be induced between the main board and the daughter board, resulting in incomplete mechanical and thermal contact between the associated heat-generating components and the heatsink, or in poor electrical contact being made between the elements of the connector. Further, such varying distances may and induced skew-angle may result in excessive stress being placed on one or more element of the information handling system due to mechanical stresses on the information handling system, such as drop/shock/vibration environments. Furthermore, due to the fact that the elements of the connector are typically soldered down to their respective boards, any damage done to a connector element may result in the need to rework the board to replace the connector element.

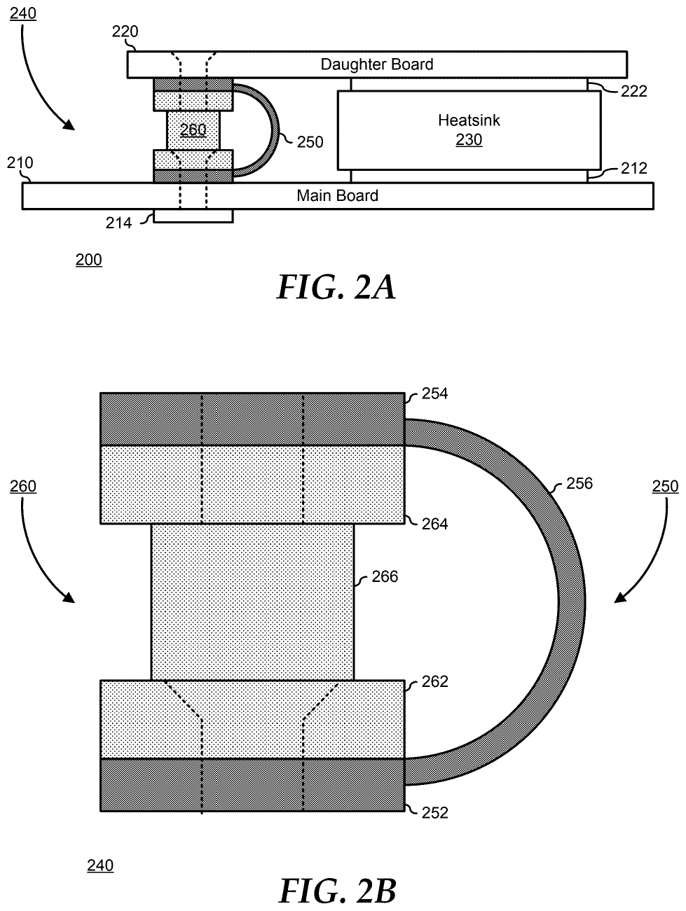

FIG. 2A illustrates an information handling system 200 similar to information handling system 100 and including a main board 210, a daughter board 220, a heatsink 230, and a connector arrangement 240. Main board 210 includes a component 212 and daughter board 220 includes a component 222. Components 212 and 222 may be understood to represent integrated circuit devices that generate large amounts of heat when in operation. For example, component 212 may represent a processor, a system-on-a-chip (SoC), another heat-generating device, or the like, and component 222 may represent a graphics processor, a chipset component, another heat-generating device, or the like. As such, information handling system 200 is arranged in a compact arrangement where main board 210 is on the bottom of the information handling system with component 212 on the top of the main board. Heatsink 230 is firmly thermally and mechanically affixed to the top of component 212 to remove heat from the component. Information handing system 200 is further arranged with daughter board 220 located above main board 210 with component 222 on the bottom of the daughter board. Heatsink 230 is further firmly thermally and mechanically affixed to the bottom of component 222 to remove heat from the component. Thus, the compactness of information handling system 200 is enhanced by combining the thermal solutions for components 212 and 222 into a single element, viz., heatsink 230.

Daughter board 220 is electrically connected to main board 210 by connector arrangement 240. In this regard, connector arrangement 240 includes a flexible flex connector 250 and a floating connector mount 260. FIG. 2B illustrates the elements of connector arrangement 240. Flex connector 250 includes a main board compression connector 252, a daughter board compression connector 254, and a flex cable 256 to connect the main board compression connector to the daughter board compression connector. Main board compression connector 252 represents a z-axis, or “vertical,” compression connectors that include separate metal compression contact elements on the bottom surface of the compression connector, one contact element for each signal line and power line provided from main board 210 to daughter board 220. Similarly, daughter board compression connector 254 represents z-axis compression connectors that include associated metal compression contact elements on the top surface of the compression connector. Each contact element of main board compression connector 252 is connected to a contact element of daughter board compression connector 254. The associated contact elements are connected together by an associated trace on flex cable 256.

Here, rather than being rigidly affixed to main board 210, such as where main board connector element 142 is soldered to main board 110, the main board includes compression connector contact pads, each pad being associated with one of the compression contact elements of the main board compression connector, and the main board compression connector is separately affixed to the main board by a screw and bolster arrangement, as described further below. Similarly, daughter board 220 includes compression connector contact pads, each pad being associated with one of the compression contact elements of daughter board compression connector 254, and the daughter board compression connector is separately affixed to the daughter board by a screw and bolster arrangement, as described further below. In this way, if any of the elements of flex connector 250 are damaged, no rework is necessary on either main board 210 or daughter board 220. Examples of compression connectors 252 and 254 may include cStack or mezzanine-type connectors from Amphenol, or the like.

In contrast to connector 140 as described above, connector arrangement 240 provides a flexible mechanical attachment between main board 210 and daughter board 220 to adaptably account for the varying distances and induced skew-angle as described above. In particular, connector arrangement 240 further includes a connector mount 260 that includes a main board compression connector retainer 262, a daughter board compression connector retainer 264, and one or more flexible block 266. Here, main board compression connector retainer 262 is rigidly affixed to compress main board compression connector 252 to main board 210, for example, by inserting a screw through the compression connector retainer and the compression connector to a bolster 214 in the main board. In this regard, main board compression connector retainer 262 includes one or more beveled through hole and main board compression connector retainer 262 includes one or more associated through hole, as indicated by the dashed lines. Similarly, daughter board compression connector retainer 264 is rigidly affixed to compress daughter board compression connector 254 to daughter board 220, for example, by inserting a screw through the daughter board and the compression connector to the compression connector retainer which acts as a bolster. In this regard, daughter board 220 includes one or more beveled through holes and daughter board compression connector 254 includes one or more associated through holes, as indicated by the dashed lines.

The flexibility of the attachment between main board 210 and daughter board 220 is provided by flexible block 266. In particular, flexible block 266 is affixed to one of main board compression connector retainer 262 or daughter board compression connector retainer 264, as needed or desired. Flexible block 266 represents a block of compressible material, such as a low durometer rubber, a polyurethane foam, or other foam rubber, a sponge-like material, or the like, and is characterized by the fact that the flexible block resists compression. That is, flexible block 266 provides an outward pressure to ensure that main board 210 and daughter board 220 remain aligned, and any distance variances in heatsink 230 or an induced skew angle between the main board and the daughter board are absorbed by the flexible block. In a particular embodiment, flexible block 266 may have a dimension such that, when stacked with main board compression connector 252, daughter board compression connector 254, main board compression connector retainer 262, and daughter board compression connector retainer 264, the stack-up height of connector arrangement 240 has a height substantially equal to the maximum height of the stack-up of component 212, component 222, and heatsink 230. In this way, if the height of the stack-up of component 212, component 222, and heatsink 230 is less than the maximum height, due, for example, to stack-up tolerances of the components and the heatsink, connector arrangement 240, and particularly flexible block 262, may be compressed to match the actual stack-up height.

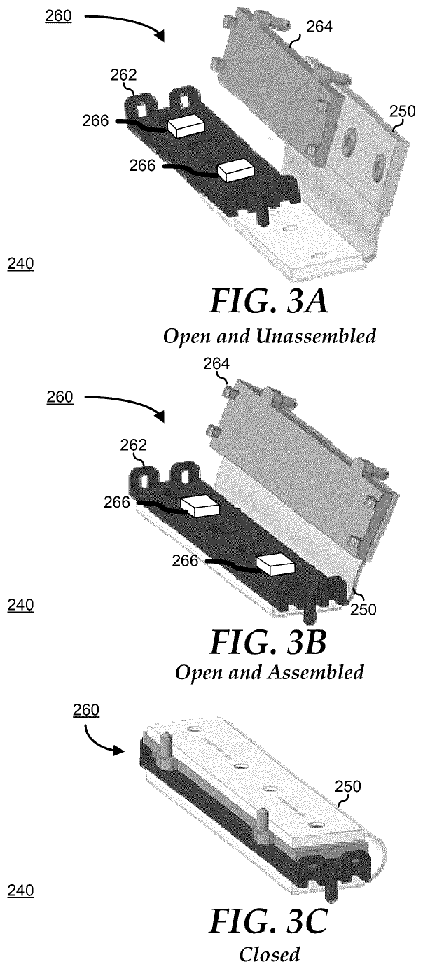

FIGS. 3A-3C illustrate an assembly process for connector arrangement 240. In FIG. 3A, connector arrangement 240 is shown in an open and unassembled configuration with the connector arrangement separated into flex connector 250 and connector mount 260. Further, connector mount 260 is shown as separate parts: main board compression connector retainer 262 and daughter board compression connector retainer 264. Main board compression connector retainer 262 is shown with two (2) flexible blocks 266 affixed thereto. In a particular embodiment, flexible blocks 266 are affixed to main board compression connector retainer 262 by adhesive. In another embodiment, one or more flexible block 266 is affixed to daughter board compression connector retainer 264.

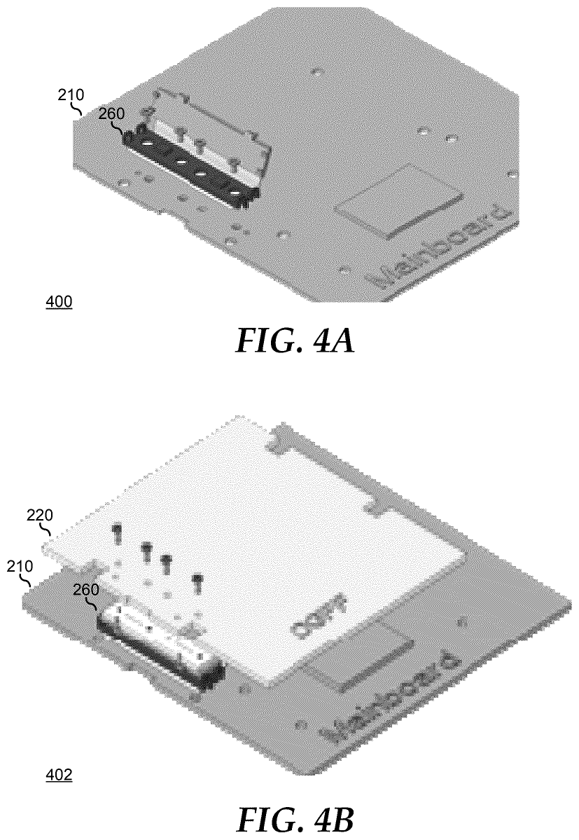

In FIG. 3B, connector arrangement 240 is shown in an open and assembled configuration with a back side of main board compression connector 252 (i.e., a side opposite the contact elements) affixed to main board compression connector retainer 262, and with a back side of daughter board compression connector 254 affixed to daughter board compression connector retainer 264. In a particular embodiment compression connectors 252 and 254 are affixed to associated compression connector retainers 262 and 264 by adhesive. In this configuration, connector arrangement 240 can be electrically connected and mechanically affixed to a main board such as main board 210 (illustrated in FIG. 2), by positioning the mounting arrangement at an associated location and affixing screws through main board compression connector retainer 262 and main board compression connector 252 to a bolster in the main board. This assembly step is shown in FIG. 4A.

In FIG. 3C, connector arrangement 240 is shown in a closed configuration with daughter board compression connector retainer 264 closed to main board compression connector retainer 262. Note that to main board compression connector retainer 262 and daughter board compression connector retainer 264 are configured with hook and latch features that maintain connector mount 260 in the closed position. In this configuration, connector arrangement 240 can be electrically connected and mechanically affixed to a daughter board such as daughter board 220 (illustrated in FIG. 2), by positioning the daughter board at an associated location and affixing screws through the daughter board and daughter board compression connector 252 to daughter board compression connector retainer 264 which acts as a bolster. This assembly step is shown in FIG. 4B.

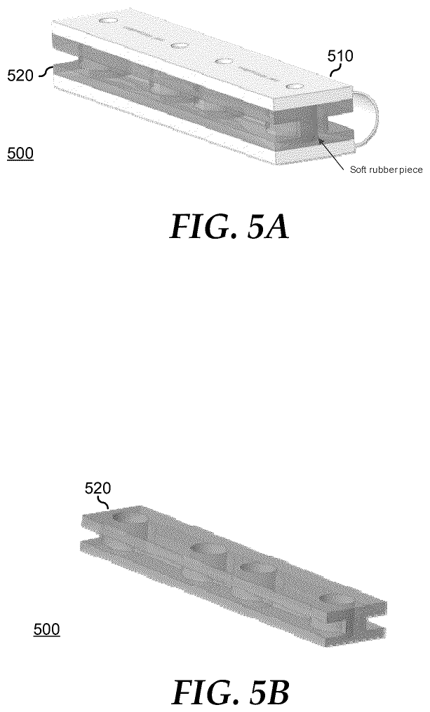

FIGS. 5A and 5B illustrate a connector arrangement 500 including a flex connector 510 and a connector mount 520. Flex connector 510 is similar to flex connector 250, being configured to be mechanically affixed and electrically connected to a main board and likewise mechanically affixed and electrically connected to a daughter board, as described above. However, here, connector mount 520 represents a single piece part that combines the functionality of the individual elements of connector mount 260. In particular, a bottom surface of connector mount 520 is mechanically affixed to a top side of the main board compression connector of flex connector 510, and a top side of the connector amount is mechanically affixed to a bottom side of the daughter board compression connector of the flex connector. Here, connector mount 520 is fabricated of a flexible and compressible material, such as a low durometer rubber, a polyurethane foam, or other foam rubber, a sponge-like material, or the like. In a particular embodiment, the top and bottom surfaces of connector mount 520 are affixed to the associated compression connectors by a adhesive, by an over-mold process, or the like.

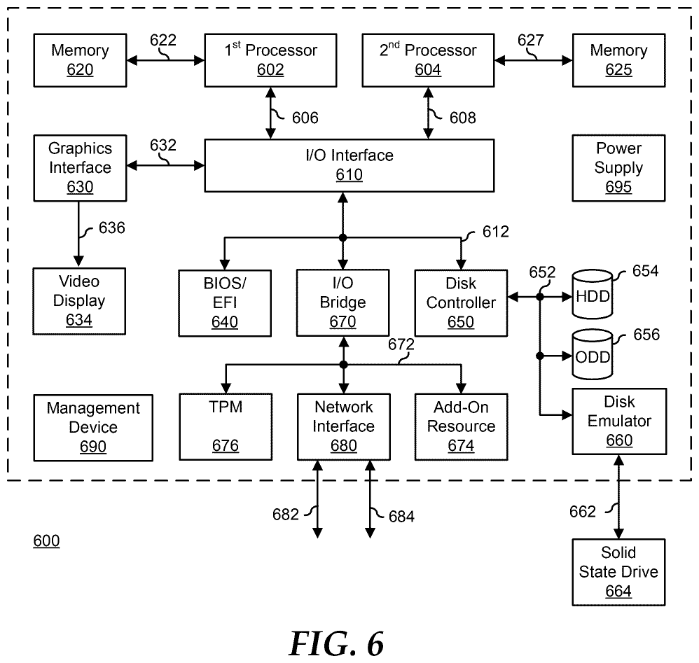

FIG. 6 illustrates a generalized embodiment of an information handling system 600 similar to information handling system 600. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 600 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 600 can include processing resources for executing machine-executable code, such as a central processing unit (CPU), a programmable logic array (PLA), an embedded device such as a System-on-a-Chip (SoC), or other control logic hardware. Information handling system 600 can also include one or more computer-readable medium for storing machine-executable code, such as software or data. Additional components of information handling system 600 can include one or more storage devices that can store machine-executable code, one or more communications ports for communicating with external devices, and various input and output (I/O) devices, such as a keyboard, a mouse, and a video display. Information handling system 600 can also include one or more buses operable to transmit information between the various hardware components.

Information handling system 600 can include devices or modules that embody one or more of the devices or modules described below, and operates to perform one or more of the methods described below. Information handling system 600 includes a processors 602 and 604, an input/output (I/O) interface 610, memories 620 and 625, a graphics interface 630, a basic input and output system/universal extensible firmware interface (BIOS/UEFI) module 640, a disk controller 650, a hard disk drive (HDD) 654, an optical disk drive (ODD) 656, a disk emulator 660 connected to an external solid state drive (SSD) 662, an I/O bridge 670, one or more add-on resources 674, a trusted platform module (TPM) 676, a network interface 680, a management device 690, and a power supply 695. Processors 602 and 604, I/O interface 610, memory 620, graphics interface 630, BIOS/UEFI module 640, disk controller 650, HDD 654, ODD 656, disk emulator 660, SSD 662, I/O bridge 670, add-on resources 674, TPM 676, and network interface 680 operate together to provide a host environment of information handling system 600 that operates to provide the data processing functionality of the information handling system. The host environment operates to execute machine-executable code, including platform BIOS/UEFI code, device firmware, operating system code, applications, programs, and the like, to perform the data processing tasks associated with information handling system 600.

In the host environment, processor 602 is connected to I/O interface 610 via processor interface 606, and processor 604 is connected to the I/O interface via processor interface 608. Memory 620 is connected to processor 602 via a memory interface 622. Memory 625 is connected to processor 604 via a memory interface 627. Graphics interface 630 is connected to I/O interface 610 via a graphics interface 632, and provides a video display output 636 to a video display 634. In a particular embodiment, information handling system 600 includes separate memories that are dedicated to each of processors 602 and 604 via separate memory interfaces. An example of memories 620 and 630 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 640, disk controller 650, and I/O bridge 670 are connected to I/O interface 610 via an I/O channel 612. An example of I/O channel 612 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 610 can also include one or more other I/O interfaces, including an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. BIOS/UEFI module 640 includes BIOS/UEFI code operable to detect resources within information handling system 600, to provide drivers for the resources, initialize the resources, and access the resources. BIOS/UEFI module 640 includes code that operates to detect resources within information handling system 600, to provide drivers for the resources, to initialize the resources, and to access the resources.

Disk controller 650 includes a disk interface 652 that connects the disk controller to HDD 654, to ODD 656, and to disk emulator 660. An example of disk interface 652 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 660 permits SSD 664 to be connected to information handling system 600 via an external interface 662. An example of external interface 662 includes a USB interface, an IEEE 1394 (Firewire) interface, a proprietary interface, or a combination thereof. Alternatively, solid-state drive 664 can be disposed within information handling system 600.

I/O bridge 670 includes a peripheral interface 672 that connects the I/O bridge to add-on resource 674, to TPM 676, and to network interface 680. Peripheral interface 672 can be the same type of interface as I/O channel 612, or can be a different type of interface. As such, I/O bridge 670 extends the capacity of I/O channel 612 where peripheral interface 672 and the I/O channel are of the same type, and the I/O bridge translates information from a format suitable to the I/O channel to a format suitable to the peripheral channel 672 where they are of a different type. Add-on resource 674 can include a data storage system, an additional graphics interface, a network interface card (NIC), a sound/video processing card, another add-on resource, or a combination thereof. Add-on resource 674 can be on a main circuit board, on separate circuit board or add-in card disposed within information handling system 600, a device that is external to the information handling system, or a combination thereof.

Network interface 680 represents a NIC disposed within information handling system 600, on a main circuit board of the information handling system, integrated onto another component such as I/O interface 610, in another suitable location, or a combination thereof. Network interface device 680 includes network channels 682 and 684 that provide interfaces to devices that are external to information handling system 600. In a particular embodiment, network channels 682 and 684 are of a different type than peripheral channel 672 and network interface 680 translates information from a format suitable to the peripheral channel to a format suitable to external devices. An example of network channels 682 and 684 includes InfiniBand channels, Fibre Channel channels, Gigabit Ethernet channels, proprietary channel architectures, or a combination thereof. Network channels 682 and 684 can be connected to external network resources (not illustrated). The network resource can include another information handling system, a data storage system, another network, a grid management system, another suitable resource, or a combination thereof.

Management device 690 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 600. In particular, management device 690 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 600, such as system cooling fans and power supplies. Management device 690 can include a network connection to an external management system, and the management device can communicate with the management system to report status information for information handling system 600, to receive BIOS/UEFI or system firmware updates, or to perform other task for managing and controlling the operation of information handling system 600. Management device 690 can operate off of a separate power plane from the components of the host environment so that the management device receives power to manage information handling system 600 where the information handling system is otherwise shut down. An example of management device 690 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 690 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A connector apparatus for electrically connecting and mechanically affixing a first printed circuit board (PCB) to a second PCB, the connector apparatus comprising:
a flex connector having a first compression connector configured to provide electrical connections to the first PCB, a second compression connector configured to provide electrical connections to the second PCB, and a flex cable coupled to the first and
second compression connectors; and
a connector mount coupled between the first and second compression connectors.

2. The connector apparatus of claim 1, wherein the connector mount is compressible.

3. The connector apparatus of claim 1, wherein the connector mount includes a first retainer configured to be coupled to the first compression connector and the first PCB, and a second retainer configured to be coupled to the second compression connector and the second PCB.

4. The connector apparatus of claim 3, wherein the connector mount further includes a compressible block between the first and second retainers.

5. The connector apparatus of claim 4, wherein the compressible block is made of one of a low durometer rubber, a polyurethane foam, and a sponge-like material.

6. The connector apparatus of claim 3, wherein the connector mount is configurable in an open position and a closed position.

7. The connector apparatus of claim 6, wherein, when the connector mount is in the open position, the first retainer is coupled to the first compression connector and the first PCB by screwing a first screw through the first retainer and the first compression connector to a bolster of the first PCB.

8. The connector apparatus of claim 7, wherein, after screwing the first screw through the first retainer and the first compression connector to the bolster of the first PCB, the connector mount is retained in the closed position.

9. The connector apparatus of claim 8, wherein, when the connector mount is retained in the closed position, the second retainer is coupled to the second compression connector and the second PCB by screwing a second screw through the first PCB and the second compression connector to a bolster of the second retainer.

10. The connector apparatus of claim 8, wherein the connector mount is retained in the closed position by a hook and latch mechanism on the first and second retainers.

11. An information handling system, comprising:
a first printed circuit board (PCB);
a second PCB; and
a connector apparatus for electrically connecting and mechanically affixing the first PCB to the second PCB, wherein the connector apparatus includes:
a flex connector having a first compression connector configured to provide electrical connections to the first PCB, a second compression connector configured to provide electrical connections to the second PCB, and a flex cable coupled to the first and second compression connectors; and
a connector mount coupled between the first and second compression connectors.

12. The information handling system of claim 11, wherein the connector mount is compressible.

13. The information handling system of claim 11, wherein the connector mount includes a first retainer configured to be coupled to the first compression connector and the first PCB, and a second retainer configured to be coupled to the second compression connector and the second PCB.

14. The information handling system of claim 13, wherein the connector mount further includes a compressible block between the first and second retainers.

15. The information handling system of claim 14, wherein the compressible block is made of one of a low durometer rubber, a polyurethane foam, and a sponge-like material.

16. The information handling system of claim 13, wherein the connector mount is configurable in an open position and a closed position.

17. The information handling system of claim 16, wherein, when the connector mount is in the open position, the first retainer is coupled to the first compression connector and the first PCB by screwing a first screw through the first retainer and the first compression connector to a bolster of the first PCB.

18. The information handling system of claim 17, wherein, after screwing the first screw through the first retainer and the first compression connector to the bolster of the first PCB, the connector mount is retained in the closed position.

19. The information handling system of claim 18, wherein, when the connector mount is retained in the closed position, the second retainer is coupled to the second compression connector and the second PCB by screwing a second screw through the first PCB and the second compression connector to a bolster of the second retainer.

20. A method for electrically connecting and mechanically affixing a first printed circuit board (PCB) to a second PCB, the method comprising:
providing a flex connector having a first compression connector configured to provide electrical connections to the first PCB, a second compression connector configured to provide electrical connections to the second PCB, and a flex cable coupled to the first and second compression connectors;
providing a connector mount coupled between the first and second compression connectors;
electrically coupling the first compression connector to the first PCB and mechanically affixing the first PBC through the first compression connector to the connector mount; and
electrically coupling the second compression connector to the second PCB and mechanically affixing the second PBC through the second compression connector to the connector mount.
